(19) United States
(12) Patent Application Publication
(10) Pub. No.: US 2025/0232987 A1
(43) Pub. Date: Jul. 17, 2025

(54) SUBSTRATE PROCESSING APPARATUS AND SUBSTRATE PROCESSING METHOD INCLUDING A PRE-TREATMENT PROCESS OF SUPPLYING A HEATED FLUID TO A SECOND SURFACE OF A SUBSTRATE AND SUPPLYING A PRE-WETTING LIQUID TO A FIRST SURFACE OF THE SUBSTRATE, WHILE ROTATING THE SUBSTRATE

(71) Applicant: Tokyo Electron Limited, Tokyo (JP)

(72) Inventor: Boi IKEDA, Koshi City (JP)

(73) Assignee: Tokyo Electron Limited, Tokyo (JP)

(21) Appl. No.: 19/023,119

(22) Filed: Jan. 15, 2025

(30) Foreign Application Priority Data
Jan. 16, 2024 (JP) 2024-004745

(51) Int. Cl. H01L 21/67; H01L 21/687

(52) U.S. Cl. CPC H01L 21/67051; H01L 21/67248; H01L 21/67276; H01L 21/68764

(57) ABSTRACT

A substrate processing apparatus includes a substrate holder for holding a substrate having a first surface and a second surface in a horizontal posture; a rotational driver for rotating the substrate holder; a first fluid supply for supplying a fluid to the first surface; a second fluid supply for supplying a fluid to the second surface; and a controller. The controller performs: a pre-treatment process of supplying a heated fluid to the second surface and supplying a pre-wetting liquid to the first surface, while rotating the substrate at a first rotation speed; and a chemical liquid treatment process of performing, after the pre-treatment process is performed, a chemical liquid treatment on the first surface by supplying a chemical liquid to the first surface and concurrently supplying the heated fluid to the second surface intermittently, while rotating the substrate at a second rotation speed.

### CROSS-REFERENCE TO RELATED APPLICATION

This application claims the benefit of Japanese Patent Application No. 2024-004745 filed on Jan. 16, 2024, the entire contents of which is incorporated herein by reference.

### TECHNICAL FIELD

The various aspects and embodiments described herein pertain generally to a substrate processing apparatus and a substrate processing method.

### BACKGROUND

In the manufacture of semiconductor devices, chemical liquid treatments such as wet etching and chemical liquid cleaning of a substrate are performed by supplying a chemical liquid to a front surface of the substrate while rotating the substrate by a spin chuck. In order to uniform a temperature distribution of the substrate for the purpose of improving in-plane uniformity of the chemical liquid treatments, a temperature control liquid is supplied to a rear surface of the substrate (see, for example, Patent Document 1).
Patent Document 1: Japanese Patent Laid-open Publication No. 2015-057816

### SUMMARY

In an exemplary embodiment, a substrate processing apparatus includes a substrate holder configured to hold a substrate having a first surface and a second surface in a horizontal posture; a rotational driver configured to rotate the substrate holder and the substrate held by the substrate holder around a vertical axis; a first fluid supply configured to supply a fluid to the first surface of the substrate held by the substrate holder; a second fluid supply configured to supply a fluid to the second surface of the substrate held by the substrate holder; and a controller. The controller controls the rotational driver, the first fluid supply and the second fluid supply to perform: a pre-treatment process of supplying a heated fluid to the second surface of the substrate and supplying a pre-wetting liquid to the first surface of the substrate, while rotating the substrate at a first rotation speed; and a chemical liquid treatment process of performing, after the pre-treatment process is performed, a chemical liquid treatment on the first surface by supplying a chemical liquid to the first surface of the substrate and concurrently supplying the heated fluid to the second surface of the substrate intermittently, while rotating the substrate at a second rotation speed.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic transversal cross sectional view of a substrate processing system according to an exemplary embodiment of a substrate processing apparatus;

FIG. 2 is a schematic longitudinal cross sectional view illustrating a configuration example of a processing device belonging to the substrate processing system of FIG. 1;

FIG. 3 is a piping system diagram illustrating a configuration example of a DIW supply mechanism for temperature control of the processing device of FIG. 2;

FIG. 4A to FIG. 4D are schematic side views illustrating a state in which individual sub-processes of a chemical liquid treatment process are being performed;

FIG. 5 is a diagram illustrating a variation in a temperature profile when a rear-surface non-heating scan discharge sub-process S2 is being performed;

FIG. 6 is a time chart for describing an example of a processing recipe performed in the processing device of FIG. 2;

FIG. 7 is a graph showing a temperature variation of a wafer when a processing shown in FIG. 6 is being performed; and

FIG. 8 is a diagram of controller circuitry used to control process operations, such as the substrate processing apparatus of FIG. 1 and other processes and equipment described herein.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, an exemplary embodiment of a substrate processing apparatus will be described with reference to the accompanying drawings.

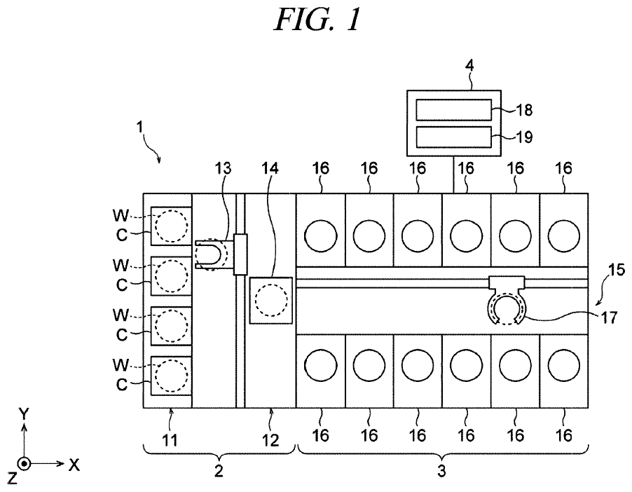

FIG. 1 is a diagram illustrating a schematic configuration of a substrate processing system according to the present exemplary embodiment. In the following description, in order to clarify positional relationships, the X-axis, Y-axis, and Z-axis that are orthogonal to each other are defined, and the positive Z-axis direction is defined as a vertically upward direction.

As depicted in FIG. 1, a substrate processing system 1 is equipped with a carry-in/out station 2 and a processing station 3. The carry-in/out station 2 and the processing station 3 are provided adjacent to each other.

The carry-in/out station 2 includes a carrier placement section 11 and a transfer section 12. A plurality of carriers C each of which accommodates a plurality of substrates (in the present exemplary embodiment, semiconductor wafers (hereinafter, simply referred to as wafers W)) horizontally are arranged in the carrier placement section 11.

The transfer section 12 is provided adjacent to the carrier placement section 11, and has therein a substrate transfer device 13 and a delivery module 14 (e.g., a delivery structure). The substrate transfer device 13 is equipped with a wafer holding mechanism (e.g., wafer holding structure) configured to hold the wafer W. Further, the substrate transfer device 13 is configured to be movable horizontally and vertically and pivotable around a vertical axis, and serves to transfer the wafer W between the carrier C and the delivery module 14 by using the wafer holding mechanism.

The processing station 3 is provided adjacent to the transfer section 12. The processing station 3 is equipped with a transfer section 15 and a plurality of processing devices 16. The plurality of processing devices 16 are arranged on both sides of the transfer section 15.

The transfer section 15 has a substrate transfer device 17 inside. The substrate transfer device 17 is equipped with a wafer holding mechanism (e.g., wafer holding structure) configured to hold the wafer W. Also, the substrate transfer device 17 is configured to be movable horizontally and vertically and pivotable around a vertical axis, and serves to transfer the wafer W between the delivery module 14 and the processing device 16 by using the wafer holding mechanism.

The processing device 16 is configured to perform a predetermined substrate processing on the wafer W transferred by the substrate transfer device 17.

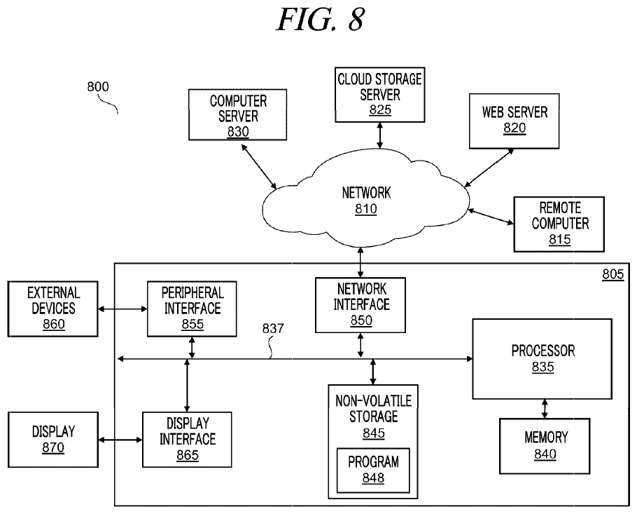

Furthermore, the substrate processing system 1 includes a control device 4, which may be implemented as the processing circuitry 805, discussed later in reference to FIG. 8. The control device 4 is, for example, a computer having circuitry, and has an operation processor 18 (e.g., such as a central processing unit (CPU)) and a storage 19 (e.g., a memory such as a read only memory (ROM) and/or a random access memory (RAM)). The storage 19 stores therein programs for controlling various processes performed in the substrate processing system 1. The operation processor 18 controls an operation of the substrate processing system 1 by reading and executing the programs stored in the storage 19.

In addition, these programs may be recorded on a computer-readable recording medium and installed from the recording medium into the storage 19 of the control device 4. The computer-readable recording medium may be, by way of non-limiting example, a hard disk (HD), a flexible disk (FD), a compact disk (CD), a magnet optical disk (MO), a memory card, or the like.

In the substrate processing system 1 configured as described above, the substrate transfer device 13 of the carry-in/out station 2 takes out the wafer W from the carrier C placed in the carrier placement sections 11, and places the taken wafer W in the delivery module 14. The wafer W placed in the delivery module 14 is taken out from the delivery module 14 by the substrate transfer device 17 of the processing station 3 and is then carried into the processing device 16.

The wafer W carried into the processing device 16 is processed by the processing device 16, then carried out from the processing device 16 by the substrate transfer device 17, and placed in the delivery module 14. Thereafter, the processed wafer W placed in the delivery module 14 is returned back into the carrier C of the carrier placement section 11 by the substrate transfer device 13.

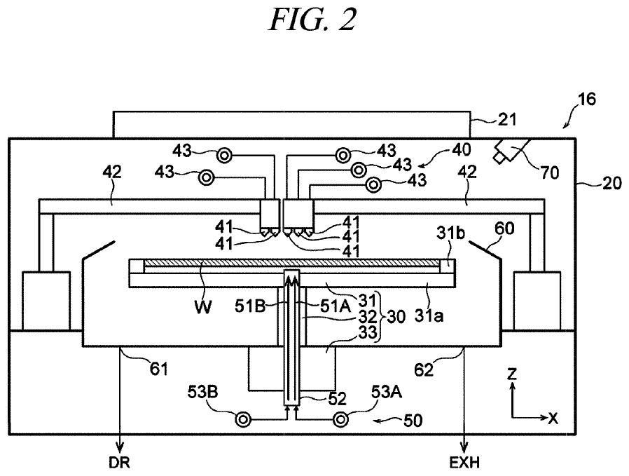

Now, a configuration of the processing device 16 will be explained with reference to FIG. 2.

The processing device 16 is equipped with a chamber 20, a substrate holding/rotating mechanism 30 (e.g., a substrate holding/rotating structure), a first processing fluid supply (first fluid supply) 40, a second processing fluid supply (second fluid supply) 50, and a liquid receiving cup 60.

The substrate holding/rotating mechanism 30 and the liquid receiving cup 60 are accommodated in the chamber 20. A fan filter unit (FFU) 21 is provided at a ceiling portion of the chamber 20. The FFU 21 creates a downflow within the chamber 20.

The substrate holding/rotating mechanism 30 includes a substrate holder 31, a supporting column 32, and a rotational driver 33. The substrate holder 31 is configured as a mechanical chuck having a disk-shaped base 31a and a plurality of gripping claws 31b provided on an outer peripheral portion of the base 31a at a regular distance therebetween in a circumferential direction. The substrate holder 31 holds the wafer W horizontally with the gripping claws 31b. When the substrate is held by the plurality of gripping claws 31b, a gap is formed between a top surface of the base 31a and a bottom surface of the wafer W.

The supporting column 32 is a vertically extending hollow member/hollow structure. An upper end of the supporting column 32 is connected to the base 31a. As the rotational driver 33 rotates the supporting column 32, the substrate holder 31 and the wafer W held by it are rotated around a vertical axis.

The liquid receiving cup 60 is disposed to surround the substrate holder 31. The liquid receiving cup 60 collects a processing liquid scattered from the wafer W held and being rotated by the substrate holder 31. A drain port 61 is formed at a bottom of the liquid receiving cup 60. The processing liquid collected by the liquid receiving cup 60 is drained from the drain port 61 to the outside of the processing device 16. Also, an exhaust port 62 is provided at the bottom of the liquid receiving cup 60. An internal space of the liquid receiving cup 60 is suctioned through the exhaust port 62. The gas supplied from the FFU 21 is drawn into the liquid receiving cup 60, and is then exhausted to the outside of the processing device 16 through the exhaust port 62.

The first processing fluid supply 40 supplies various types of processing fluids (a liquid, a gas, a gas-liquid mixed fluid, etc.) to a top surface of the wafer W (typically, a front surface of the wafer W on which devices are formed) held by the substrate holder 31. The first processing fluid supply 40 includes a plurality of front surface nozzles 41 configured to respectively discharge the processing fluids toward the top surface (first surface) of the wafer W. Here, the number of the front surface nozzles 41 is provided as many as necessary to perform the processes performed in the processing device 16. Although five front surface nozzles 41 are shown in FIG. 2, the number thereof is not limited thereto.

The first processing fluid supply 40 has one or more (two in the shown example) nozzle arms (nozzle moving structures/nozzle moving mechanisms) 42. Each nozzle arm 42 holds at least one of the plurality of front surface nozzles 41. Each nozzle arm 42 is capable of moving the front surface nozzle 41 held thereby between a position (processing position) approximately directly above a rotation center of the wafer W and a retreated position outside the upper end opening of the liquid receiving cup 60. The nozzle arm 42 may be of a type configured to pivot around a pivot axis, or of a type configured to move in a translational manner.

Each of the front surface nozzles 41 is supplied with a processing fluid from a processing fluid supply mechanism (e.g., processing fluid supplier) 43 (which is a part of the first processing fluid supply 40) corresponding thereto. The processing fluid supply mechanism 43 can be composed of a processing fluid source such as a tank, a cylinder or a factory supply, a supply line through which the processing fluid from the processing fluid source is supplied to the front surface nozzle 41, and a flow rate control mechanism (e.g., flow rate controller) such as an opening/closing valve and a flow rate control valve provided in the supply line. A drain line may be connected to the supply line in order to drain the processing fluid (particularly, the processing liquid) remaining in the front surface nozzle 41 and the supply line in the vicinity thereof. Such a processing fluid supply mechanism 43 is well known in the technical field of semiconductor manufacturing equipment, so a detailed description of its structure will be omitted here. The processing device 16 is provided with a liquid receiver so that dummy dispensing is possible when each front surface nozzle 41 is at the retreated position.

The second processing fluid supply 50 supplies various types of processing fluids (a processing liquid, a processing gas, etc.) to a bottom surface of the wafer W (typically a rear surface of the wafer W on which no device is formed) held by the substrate holder 31. The second processing fluid supply 50 has one or more (two in the shown example) rear surface nozzles 51A and 51B configured to respectively discharge the processing fluids toward the bottom surface (second surface) of the wafer W. As schematically shown in FIG. 2, a processing liquid supply line 52 vertically extends within the hollow supporting column 32. Upper end openings of two flow paths extending vertically in the processing liquid supply line 52 function as the rear surface nozzles 51A and 51B, respectively. The processing liquid supply line 52 is installed inside the supporting column 32 so that it can maintain a non-rotating state even when the substrate holder 31 and the supporting column 32 are being rotated.

Heated DIW (de-ionized water/pure water) for controlling the temperature of the wafer W is supplied to the rear surface nozzle 51A (heated fluid nozzle) from a temperature control DIW supply mechanism (temperature control DIW supplier) 53A (which is a part of the second processing fluid supply 50). The rear surface nozzle 51A and the temperature control DIW supply mechanism 53A constitute a supply mechanism for a heated fluid (temperature control fluid). The rear surface nozzle 51B may be supplied with DIW of a room temperature, a nitrogen gas, or the like, from the processing fluid supply mechanism 53B.

In the present disclosure, the DIW of the room temperature (e.g., 24° C.) is referred to as “CDIW” to distinguish it from “HDIW,” which denotes the heated DIW.

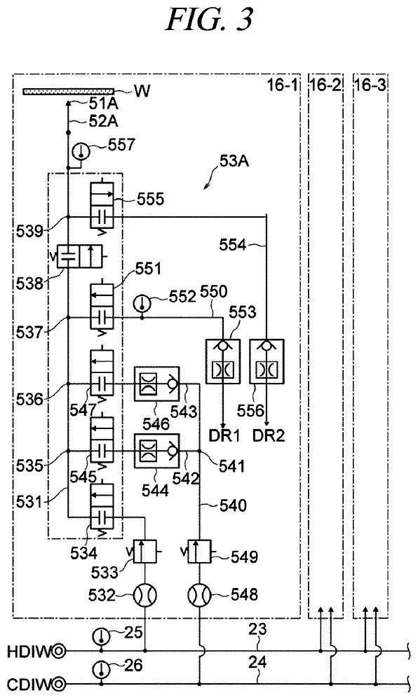

Now, a configuration of the temperature control DIW supply mechanism 53A for the rear surface nozzle 51A will be explained with reference to FIG. 3. The temperature control DIW supply mechanism 53A is provided for each of the plurality of processing devices 16 (16-1, 16-2, 16-3, . . . ) in one-to-one correspondence. The configurations of the respective temperature control DIW supply mechanisms 53A are substantially the same.

The substrate processing system 1 has a HDIW branch line 23 connected to a HDIW source, and a CDIW branch line 24 connected to a CDIW source. The branch lines 23 and 24 respectively supply the HDIW and the CDIW to all of the plurality of processing devices 16 provided in the single substrate processing system 1. The HDIW branch line 23 is provided with a temperature sensor 25, and the CDIW branch line 24 is provided with a temperature sensor 26.

The HDIW source and the CDIW source are, for example, factory supplies of the semiconductor manufacturing factory in which the substrate processing system 1 is provided. Alternatively, the HDIW source may be, as a component of the substrate processing system 1, a tank for storing HDIW therein.

The temperature control DIW supply mechanism 53A has a main line 531 (heated fluid line) branched off from the HDIW branch line 23. The main line 531 is provided with a flow meter 532, a constant-pressure valve 533, an opening/closing valve 534, a first junction 535, a second junction 536, a first branchpoint 537, an opening/closing valve 538, and a second branchpoint 539 in order from the upstream side. A downstream end of the main line 531 is connected to the rear surface nozzle 51A through the flow path inside the processing liquid supply line 52.

The flowmeter 532 and the constant-pressure valve 533 constitute a flow rate controller configured to adjust the flow rate of the HDIW flowing through the main line 531. The constant-pressure valve 533 has a pilot port. The constant-pressure valve 533 operates such that a secondary pressure according to an operating pressure (pneumatic pressure) supplied to the pilot port from an electro-pneumatic regulator is achieved. The operating pressure supplied to the pilot port of the constant-pressure valve 533 is feedback-controlled by a control device (the control device 4 of FIG. 1, or its subordinate controller) such that a detection flow rate of the flowmeter 532 reaches a required value (set value).

The temperature control DIW supply mechanism 53A also has a dilute liquid line 540 branched off from the CDIW branch line 24. The dilute liquid line 540 is branched at a branchpoint 541 into a first branch dilute liquid line 542 for a large flow rate and a second branch dilute liquid line 543 for a small flow rate. The first branch dilute liquid line 542 is provided with a throttle 544 and an opening/closing valve 545. The second branch dilute liquid line 543 is provided with a throttle 546 and an opening/closing valve 547. In the shown example, the throttles 544 and 546 are configured as orifices (fixed throttles) mounted with check valves. The first branch dilute liquid line 542 and the second branch dilute liquid line 543 are connected to the main line 531 at the first junction 535 and the second junction 536, respectively. When it is not required to vary a mixing ratio of the CDIW and the HDIW, the dilute liquid line 540 may be connected to the main line 531 without being branched off. In this case, the second branch dilute liquid line 543, the throttle 546, and the opening/closing valve 547 are removed from the configuration shown in FIG. 3.

A flow meter 548 and a constant-pressure valve 549 are provided upstream of the branchpoint 541 of the dilute liquid line 540. The flow meter 548 and the constant-pressure valve 549 have the same configuration and function as the flow meter 532 and the constant-pressure valve 533.

A first drain line 550 is branched off from the main line 531 at the first branchpoint 537. The first drain line 550 is provided with an opening/closing valve 551, a temperature sensor 552, and a throttle 553 (in the shown example, an orifice (fixed throttle) mounted with a check valve) in order from the upstream side.

A second drain line 554 is branched off from the main line 531 at the second branchpoint 539. The second drain line 554 is provided with an opening/closing valve 555 and a throttle 556 (in the shown example, an orifice (fixed throttle) mounted with a check valve) in order from the upstream side.

A pressure sensor 557 is provided downstream of the second branchpoint 539 of the main line 531.

When the HDIW source and the CDIW source are factory supplies, the temperature of the HDIW flowing through the HDIW branch line 23 is, for example, 70° C., and the temperature of the CDIW flowing through the CDIW branch line 24 is, for example, 24° C. This temperature varies slightly due to various factors such as the temperature of the exterior air and temperature variations in a clean room, and is thus monitored by temperature sensors 25 and 26.

As will be described later, HDIW for temperature control is supplied from the rear surface nozzle 51A to the rear surface of the wafer W for the main purpose of adjusting the temperature of the wafer W. The temperature control DIW supply mechanism 53A can supply only HDIW or a mixture of HDIW and CDIW to the rear surface of the wafer W from the rear surface nozzle 51A. The temperature of the DIW supplied from the rear surface nozzle 51A to the wafer W can be adjusted by changing a mixing ratio of the HDIW and the CDIW (a ratio between a flow rate of the HDIW introduced into the main line 531 and a flow rate of the CDIW introduced into the main line 531 via the dilute liquid line 540 (542 and 543)). In an example processing to be described below, the HDIW of 65° C. is supplied to the wafer W from the rear surface nozzle 51A.

The first drain line 550 is used for an operation (also called “discarding” or “dummy dispensing”) to discard the DIW without supplying it to the wafer W until the temperature is stabilized.

The second drain line 554 is used to discard the DIW remaining in the rear surface nozzle 51A, the flow path in the processing liquid supply line 52 connected to the rear surface nozzle 51A, and a passageway in the vicinity thereof. Thus, immediately after the discharge of the DIW for temperature control from the rear surface nozzle 51A is begun, the DIW whose temperature is not controlled can be suppressed from being discharged.

Now, an example of the liquid treatment performed on the wafer W in the processing device 16 will be explained. The wafer W is held in a horizontal posture by the substrate holding/rotating mechanism 30 with its front surface as a processing target surface facing upwards, and is rotated around a vertical axis. The rotation of the wafer W is carried on until a series of processes is completed. For example, the liquid treatment to be described below can be implemented as the operation processor 18 of the control device 4 executes a control program based on a processing recipe stored in the storage 19 of the control device 4 to control the operation of the substrate processing system 1.

Furthermore, in the following description, some of the plurality of front surface nozzles 41 belonging to the first processing fluid supply 40 are appropriately utilized to supply the processing fluids to the front surface (first surface) of the wafer W. As a specific example, one front surface nozzle 41 is assigned for each of functional water as a pre-wetting liquid, a chemical liquid (organic chemical liquid), and DIW as a rinse liquid. The front surface nozzle 41 for discharging the chemical liquid may be provided on one of the plurality of nozzle arms 42, and the front surface nozzle 41 for discharging the pre-wetting liquid and the rinse liquid (both of which may be DIW) may be mounted on another one of the plurality of nozzle arms 42, but the exemplary embodiment is not limited thereto. The rear surface nozzle 51A of the second processing fluid supply 50 is used to supply HDIW, which is a processing fluid for temperature control, to the rear surface (second surface) of the wafer W.

Examples of the chemical liquid used in the processing to be described below include organic chemical liquids, such as tetramethylammonium hydroxide (TMAH), a mixed solution of TMAH and hydrogen peroxide, ammonia, SC1 (a mixture of ammonia water and hydrogen peroxide), choline, and a mixed solution of choline and hydrogen peroxide.

### [Dummy Dispensing Process]

First, the front surface nozzle 41 for discharging the chemical liquid (hereinafter, also referred to as “chemical liquid nozzle 41C”) is positioned directly above a dummy dispense port for an organic chemical liquid, which is provided outside the liquid receiving cup 60, to perform dummy dispensing of the chemical liquid. As a result, the chemical liquid of a relatively low temperature having suffered a temperature decrease in a discharge port of the chemical liquid nozzle 41C and a pipeline connected thereto is replaced with the new chemical liquid of a relatively high temperature. This makes it possible to discharge the chemical liquid of a relatively high temperature (here, about 55° C.) from immediately after starting the discharge onto the wafer W. The dummy dispensing is performed for 4 seconds at a discharge flow rate of, e.g., 700 ml/min. Conditions for the dummy dispensing are not limited thereto. The temperature of the chemical liquid discharged from the chemical liquid nozzle 41C onto the wafer W is selected appropriately depending on the type of the chemical liquid, a required etching amount, and so forth, and it may be selected from a range of, e.g., about 30° C. to about 80° C.

### [Pre-Treatment Process]

Next, the front surface nozzle 41 for discharging the pre-wetting liquid (hereinafter also referred to as “pre-wetting nozzle 41P”) is positioned directly above the center of the wafer W being rotated, and discharges the pre-wetting liquid so that it lands on the center of the wafer W. The pre-wetting liquid may be DIW (pure water), functional water in which ammonia is dissolved in DIW (for example, functional water with an ammonia concentration of 10 ppm or less), or functional water in which ozone is dissolved in DIW (for example, functional water with an ozone concentration of 20 ppm or less).

At the same time or almost at the same time (for example, about 1 second before or after) when the pre-wetting liquid starts to be discharged, the rear surface nozzle 51A starts to discharge HDIW (heated DIW) as a temperature control liquid. The temperature of the HDIW is, by way of example, but not limited to, about 65° C. The temperature of the HDIW discharged from the rear surface nozzle 51A is the same in all processes. However, the temperature of the HDIW may be varied for the individual processes. The temperature of the pre-wetting liquid is, for example, a room temperature, but heated pre-wetting liquid may be used instead.

In the following description, the position of the front surface nozzle 41 (the position in a radial direction of the wafer W with respect to a rotation center of the wafer W) and a position of a landing point of the liquid discharged from the front surface nozzle 41 on the front surface of the wafer W (the position in the radial direction of the wafer W with respect to the rotation center of the wafer W) are assumed to be corresponding to each other. Discharging the liquid from the front surface nozzle 41 to a central portion of the wafer W means discharging the liquid from the front surface nozzle 41 so that the liquid lands on the central portion of the wafer W. Also, the liquid discharged from the front surface nozzle 41 landing on the “central portion” of the wafer W is not limited to the case where the liquid discharged from the front surface nozzle 41 lands on the exact rotation center of the wafer W, but also includes a case where the liquid is diffused by the landing force to reach the exact rotation center of the wafer W. The same is applied to the liquid discharged from the rear surface nozzle 51.

The rotation speed of the wafer W in the pre-treatment process is relatively high, for example, about 1000 rpm. This is to allow the pre-wetting liquid and the HDIW to be quickly diffused over the entire front and rear surfaces of the wafer W.

In an appropriate exemplary embodiment, in the pre-treatment process, a discharge flow rate of the pre-wetting liquid is set to a relatively large flow rate of, e.g., about 700 ml/min immediately after the start of the discharge of the pre-wetting liquid, to thereby allow the entire front surface of the wafer W to be quickly covered with the pre-wetting liquid. Then, once the entire front surface of the wafer W is covered with the pre-wetting liquid, the discharge flow rate of the pre-wetting liquid is reduced to a small flow rate of about 150 ml/min.

In an appropriate exemplary embodiment, in all processes including the pre-treatment process, a discharge flow rate of the HDIW discharged from the rear surface nozzle 51A is set to a large flow rate of, e.g., 1500 ml/min. As a result, the entire rear surface of the wafer W is uniformly covered with the HDIW from immediately after the discharge of the HDIW is begun, so that the entire region of the wafer W is quickly and evenly heated by the HDIW. If the HDIW is discharged at a low flow rate, an outer peripheral portion of the wafer W would not be heated.

When the pre-wetting liquid is DIW, the pre-treatment process is performed for, e.g., about 16 seconds (but not limited thereto). When the aforementioned functional water is used as the pre-wetting liquid, a processing time of the pre-wetting process may be shortened to, for example, about 8 seconds (but not limited thereto). This is because when the aforementioned functional water is used, particles are less likely to attach to the wafer W again due to an influence of a zeta potential, or the like.

Further, in the pre-treatment process, the liquid collected by the liquid receiving cup 60 is drained into an acidic factory waste liquid line when the pre-wetting liquid is DIW or ozone water, or into an alkaline factory waste liquid line when the pre-wetting liquid is diluted ammonia water.

As is clear from the above description, the pre-treatment process has a function as a heating process for raising the temperature of the wafer W up to a temperature suitable for the corresponding chemical liquid treatment and has a function as a pre-wetting process for making the front surface of the wafer W easily wettable with the chemical liquid.

### [Chemical Liquid Treatment Process]

Upon the completion of the pre-treatment process, a chemical liquid treatment process is performed, in which the front surface of the wafer W is treated with an organic chemical liquid. The chemical liquid treatment process includes a multiple number of sub-processes. In the chemical liquid treatment process, after an initial sub-process INI is performed, a rear surface heating scan discharge sub-process S1, a rear surface non-heating scan discharge sub-process S2, a rear surface heating center discharge sub-process S3, and a rear surface non-heating center discharge sub-process S4 are performed in an appropriate combination. In the chemical liquid treatment process, the rear surface non-heating scan discharge sub-process S2 is performed at least once.

### <Initial Sub-Process INI>

Upon the completion of the pre-treatment process, the rotation speed of the wafer W is reduced to a medium speed of, e.g., about 600 rpm. The rotation speed of the wafer W during the chemical liquid treatment process is maintained at this rotation speed (here, 600 rpm). Almost concurrently with this, the discharge of the HDIW to the rear surface of the wafer W, which has been performed in the pre-treatment process, is temporarily stopped. Further, a chemical liquid with a temperature (e.g., 55° C.) higher than the room temperature is discharged from the chemical liquid nozzle 41C to the central portion of the wafer W. A discharge flow rate of this chemical liquid is set to a medium discharge flow rate of, e.g., about 500 ml/min. This state in which the discharge of the HDIW to the rear surface of the wafer W is stopped and the chemical liquid is discharged to the front surface of the wafer W is maintained for a predetermined time, for example, 3 seconds. Here, the reason for temporarily stopping the discharge of the HDIW to the rear surface of the wafer W is to suppress the temperature of the central portion of the wafer W from becoming too high as compared to the temperature of the outer peripheral portion thereof. Further, the rotation speed of the wafer W in the chemical liquid treatment process is desirably smaller than that in the pre-treatment process, but may be the same.

Subsequently, while carrying on the discharge of the chemical liquid from the chemical liquid nozzle 41C to the central portion of the wafer W at the same discharge flow rate, the discharge of the HDIW to the rear surface of the wafer W, which has been stopped, is resumed. This state is maintained for a preset time, for example, 2 seconds, which ends the initial sub-process. Besides, the initial sub-process can also be said to be the same as a combination of the rear surface non-heating center discharge sub-process S4 and the rear surface heating center discharge sub-process S3, which will be described later.

### <Rear Surface Heating Scan Discharge Sub-Process S1>

The HDIW is discharged from the rear surface nozzle 51A, and the chemical liquid is discharged from the chemical liquid nozzle 41C to the central portion of the wafer W at a relatively small discharge flow rate of, e.g., about 150 ml/min. From this state, the chemical liquid nozzle 41C is moved to move the landing point of the chemical liquid from the central portion of the wafer W to an outer peripheral portion PR of the wafer W over a period of, for example, one second (but not limited thereto). In the present specification, the outer peripheral portion PR (the term “outer peripheral portion” assigned with the notation “PR”) is used as a term meaning a specific position near the periphery (edge) of the wafer W. In the present exemplary embodiment, the outer peripheral portion PR is a position 130 mm away from the rotation center of the wafer W in the radial direction when the wafer W has a size of 12 inches.

Subsequently, with the chemical liquid nozzle 41C stopped at a position directly above the outer peripheral portion PR of the wafer W for, e.g., one second (but not limited thereto), the chemical liquid is discharged from the chemical liquid nozzle 41C to the outer peripheral portion. Then, the chemical liquid nozzle 41C is moved to move the landing point of the chemical liquid from the outer peripheral portion of the wafer W to the center of the wafer W over a period of, e.g., one second (but not limited thereto). That is, in this rear surface heating scan discharge sub-process, while discharging the HDIW from the rear surface nozzle 51A, the chemical liquid is scan-discharged from the chemical liquid nozzle 41 onto the front surface of the wafer W.

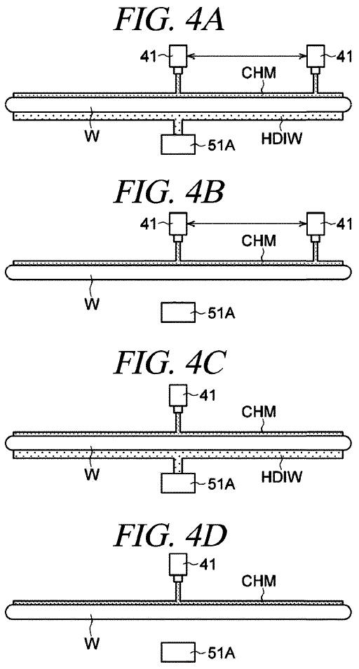

FIG. 4A schematically illustrates a state in which the rear surface heating scan discharge sub-process S1 is being performed.

### <Rear Surface Non-Heating Scan Discharge Sub-Process S2>

The rear surface non-heating scan discharge sub-process differs from the rear surface heating scan discharge sub-process only in that the HDIW is not discharged from the rear surface nozzle 51A, and the other sequences are exactly the same.

FIG. 4B schematically illustrates a state in which the rear surface non-heating scan discharge sub-process S2 is being performed.

In the rear surface heating scan discharge sub-process and the rear surface non-heating scan discharge sub-process, when the landing point of the chemical liquid discharged from the chemical liquid nozzle 41C is located away from the center of the wafer W, especially when the landing point of the chemical liquid is located at the outer peripheral portion PR, supply conditions for the chemical liquid are determined such that the chemical liquid does not run out (meaning that a region where no liquid film of the chemical liquid exists is created) at the central portion of the front surface of the wafer W. In the present exemplary embodiment, the time during which the landing point of the chemical liquid is away from the central portion of the wafer W is about 3 seconds. This time may vary depending on the rotation speed of the wafer W, the volatility and fluidity of the chemical liquid, and so forth.

In the rear surface heating scan discharge sub-process in which the HDIW is supplied from the rear surface nozzle 51A to the central portion of the rear surface of the wafer W at the large flow rate (1500 ml/min), the temperature of the central portion of the wafer W increases with a lapse of time and becomes higher than a temperature of the outer peripheral portion, and a temperature difference therebetween increases (details will be explained later).

Meanwhile, in the rear surface non-heating scan discharge sub-process in which the HDIW is not discharged from the rear surface nozzle 51A to the central portion of the rear surface of the wafer W, the temperature of the wafer W is determined by a balance between heat dissipation from the wafer and heat input from the chemical liquid supplied from the chemical liquid nozzle 41. In the present exemplary embodiment, the chemical liquid is supplied from the chemical liquid nozzle 41C at a relatively small flow rate (for example, about 150 ml/min). As the influence of the heat dissipation is greater, the temperature of the wafer W decreases in overall.

At this time, when the chemical liquid is being supplied from the chemical liquid nozzle 41C to the outer peripheral portion PR of the wafer W, the temperature decrease of the outer peripheral portion of the wafer W is suppressed by the chemical liquid, whereas the temperature of the central portion of the wafer W, where no heat is applied, decreases more than that of the outer peripheral portion PR. For this reason, a temperature difference between the central portion and the outer peripheral portion PR of the wafer W becomes smaller, or the temperature of the outer peripheral portion PR of the wafer W becomes higher than that of the central portion of the wafer W. By utilizing the temperature decrease tendency of the central portion of the wafer W in the rear surface non-heating scan discharge sub-process, thermal history in the surface of the wafer W can be equalized, and, as a result, an etching amount (a reaction amount and a processing amount) by the chemical liquid can be equalized.

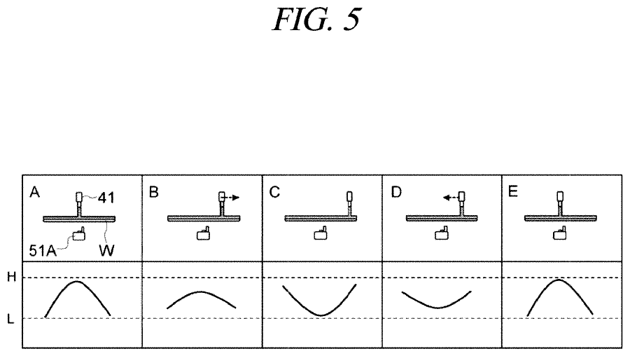

A relationship between the position of the chemical liquid nozzle 41C and the temperature profile of the wafer W in the rear surface non-heating scan discharge sub-process is shown in FIG. 5. The position of the chemical liquid nozzle 41C is shown in an upper portion of FIG. 5, and the temperature profile of the wafer W is shown in a lower portion of FIG. 5. As can be seen from this, by lengthening the time during which the chemical liquid is supplied from the chemical liquid nozzle 41C to the outer peripheral portion PR of the wafer W, the temperature of the outer peripheral portion PR of the wafer W can be temporarily made higher than the temperature of the central portion (see C and D of FIG. 5). However, as mentioned above, it is necessary to suppress the chemical liquid from running out at the central portion of the wafer W. From this point of view, it is desirable that the time during which the chemical liquid nozzle 41C is stopped at the outer peripheral portion PR of the wafer W is less than 3 seconds.

In addition, in the rear surface heating scan discharge sub-process, as the temperature profile of the wafer W is largely affected by the HDIW discharged at the large flow rate from the rear surface nozzle 51A, it is impossible or very difficult to make the temperature of the outer peripheral portion PR of the wafer W higher than the temperature of the central portion thereof as shown in FIG. 5. However, in the rear surface heating scan discharge sub-process, supplying the chemical liquid to a position (for example, the outer peripheral portion PR) away from the central portion of the wafer W is useful for bringing the temperature of the outer peripheral portion PR of the wafer W closer to the temperature of the central portion.

In the rear surface heating scan discharge sub-process, since the HDIW is supplied to the central portion of the rear surface of the wafer W, a waste liquid in the rear surface heating scan discharge sub-process is a mixture of the HDIW and the chemical liquid. When the chemical liquid is an organic chemical liquid, it must be disposed of in a waste area for the organic chemical liquid. If the HDIW is supplied at 1500 ml/min and the chemical liquid is supplied at 150 ml/min, the waste liquid is generated at 1650 ml/min. In the rear surface non-heating scan discharge sub-process, since the HDIW is not supplied to the central portion of the rear surface of the wafer W, the waste liquid is generated at 150 ml/min. As the amount of the waste liquid increases, the cost for the disposal of the waste liquid also increases, so it is desirable that the amount of the waste liquid is small. By including the rear surface non-heating scan discharge sub-process in the chemical liquid treatment process, not only the thermal history in the surface of the wafer W can be equalized, but the cost for the disposal of the waste liquid can also be cut.

### <Rear Surface Heating Center Discharge Sub-Process S3 and Rear Surface Non-Heating Center Discharge Sub-Process S4>

The rear surface heating center discharge sub-process and the rear surface non-heating center discharge sub-process are different from the rear surface heating scan discharge sub-process and the rear surface non-heating scan discharge sub-process only in that the chemical liquid nozzle 41C does not perform a scanning operation, and the other sequences are exactly the same.

FIG. 4C and FIG. 4D schematically illustrate a state in which the rear surface heating center discharge sub-process S3 is being performed and a state in which the rear surface non-heating center discharge sub-process S4 is being performed, respectively.

After performing the rear surface heating scan discharge sub-process, the rear surface non-heating scan discharge sub-process, the rear surface heating center discharge sub-process, and the rear surface non-heating center discharge sub-process in an appropriate combination, the rear surface non-heating center discharge sub-process, for example, may be performed last to end the chemical liquid treatment process, but the exemplary embodiment is not limited thereto.

### [Rinsing Process and Drying Process]

Upon the completion of the chemical liquid treatment process, a rinsing process and a drying process are performed. The rinsing process and the drying process may be performed by commonly known methods. The rinsing process may be carried out by supplying DIW as a rinse liquid to the front surface of the wafer W from the front surface nozzle 41 for discharging the rinse liquid, while rotating the wafer W. If DIW cannot be used in the rinsing process, isopropyl alcohol (IPA) may be used as the rinse liquid. Also, the rinsing process may be performed while supplying DIW to the rear surface of the wafer W from the rear surface nozzle 51A or 51B. The drying process may be carried out by rotating the wafer W at a high speed in the state where the supply of the rinse liquid to the front and rear surfaces of the wafer W is stopped. Also, the drying process may be performed while discharging a nitrogen gas to the front surface of the wafer W from the front surface nozzle 41 for discharging the nitrogen gas. The rinse liquid present on the front surface of the wafer W immediately before the drying process may be replaced with IPA.

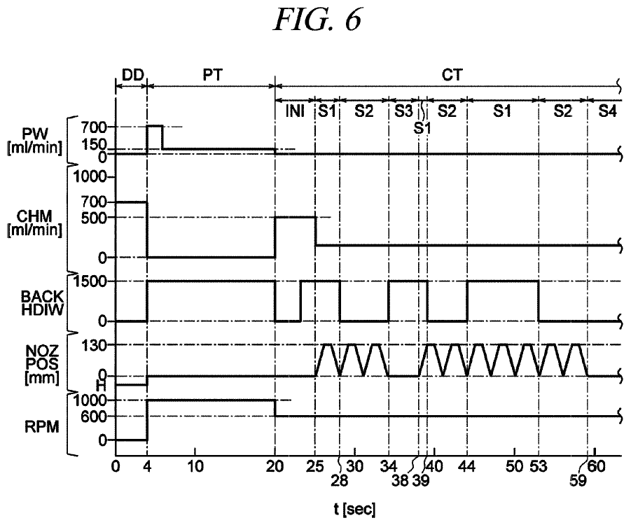

Now, an example of a processing sequence for the wafer W will be explained with reference to a graph (time chart) of FIG. 6 showing an example of a processing recipe.

A horizontal axis of the graph represents an elapsed time (in a unit of seconds) from a processing start point (a start point of the dummy dispensing process) set as time t=0 (seconds).

A vertical axis of the graph represents the following from the top.

“PW” represents the discharge flow rate (in a unit of ml/min) of the DIW or functional water as the pre-wetting liquid discharged to the central portion of the wafer W. The discharge flow rate is 0 ml/min, 150 min/min, or 700 ml/min.

“CHM” indicates the discharge flow rate (in a unit of ml/min) of the chemical liquid from the chemical liquid nozzle 41C. The discharge flow rate is 0 ml/min, 150 ml/min, 500 ml/min, or 700 ml/min.

“BACK HDIW” denotes the discharge flow rate (in a unit of ml/min) of the temperature control HDIW from the rear surface nozzle 51A. The discharge flow rate is either 0 ml/min or 1500 ml/min.

“NOZ POS” denotes the position of the chemical liquid nozzle 41C; “H,” a home position outside the liquid receiving cup; “0,” a position directly above the rotation center of the wafer W; and “130,” a position 130 mm away from the rotation center of the wafer W in the radially outward direction (corresponding to the aforementioned outer peripheral portion PR). Diagonal lines connecting “0” and “130” indicate that the nozzle is being moved.

“RPM” indicates the rotation speed (revolutions per minute) of the wafer W. The rotation speed of the wafer W is 0 rpm, 600 rpm, or 1000 rpm.

Further, when changing the rotation speed or the discharge flow rate, some ascending or descending time occurs. For this reason, a line representing the rotation speed or the like will actually slope, but this slope is not illustrated in order to simplify the graph.

First, the dummy dispensing process is performed between the time t=0 and time t=4. The dummy dispensing process is indicated by “DD” at the top of graph of FIG. 6.

Next, the pre-treatment process is performed between the time t=4 and time t=20. The pre-treatment process is indicated by “PT” at the top of the graph of FIG. 6. As explained above, the discharge flow rate of the pre-wetting liquid is set to 700 ml/min immediately after the start of the discharge, and is reduced to 150 ml/min when the entire front surface of the wafer W is covered with the pre-wetting liquid (about 1 to 2 seconds after the start of the discharge). As another example, when dilute ammonia water, which is functional water, is used as the pre-wetting liquid, the pre-treatment process is ended at t=12, and timings for the start and the end of each of the subsequent processes are advanced by 8 seconds.

Next, the chemical liquid treatment process is performed. The chemical liquid treatment process is indicated by “CT” at the top of the graph of FIG. 6. The sub-processes included in the chemical liquid treatment process are also indicated at the top of the graph of FIG. 6. Specifically, the initial sub-process is indicated by “INI”; the rear surface heating scan discharge sub-process, “S1”; the rear surface non-heating scan discharge sub-process, “S2”; the rear surface heating center discharge sub-process, “S3”; and the rear surface non-heating center discharge sub-process, “S4”. In the present exemplary embodiment, the combination of the sub-processes is determined mainly from the viewpoint of the uniformity of the thermal history in the plane of the wafer W. In the present exemplary embodiment, as long as the rear surface non-heating scan discharge sub-process S2 is included, the other sub-processes may be combined in any of various ways, and any of the sub-processes S1, S3, and S4 may not be included. The temperature of the chemical liquid discharged from the chemical liquid nozzle 41C is 55° C. in the present exemplary embodiment.

The processes after the chemical liquid treatment process (the rinsing process, the drying process, etc.) are not shown in the graph of FIG. 6.

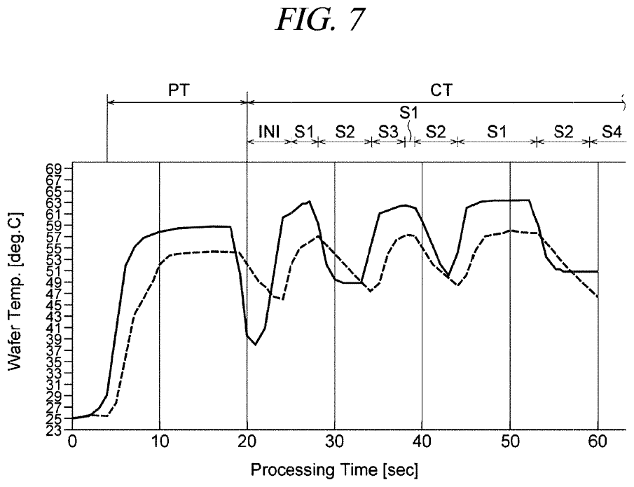

A graph of FIG. 7 shows a temperature distribution of the wafer W when the processing recipe shown in the graph of FIG. 6 is performed. In the graph of FIG. 7, a solid line indicates the temperature of the central portion of the wafer W, and a dashed line represents the temperature of the outer peripheral portion PR of the wafer W. In an upper part of the graph of FIG. 7, the periods during which the pre-treatment process PT, the chemical liquid treatment process CT, and the sub-processes INI, S1, S2, S3, and S4 of the chemical liquid treatment process CT are being performed are shown. As can be seen from the graph of FIG. 7, when the rear surface non-heating scan discharge sub-process S2 is being performed, the value of “the temperature of the central portion of the wafer W minus the temperature of the outer peripheral portion PR of wafer W” decreases, and in some cases, the value is negative (that is, the temperature of the outer peripheral portion PR of the wafer W becomes higher than the temperature of the central portion thereof).

A processing result obtained when the processing recipe shown in the graph of FIG. 6 (hereinafter, also referred to as “experimental example”) is performed will be compared with a processing result according to a conventional recipe (hereinafter, also referred to as “comparative example”). According to the conventional recipe, no temperature control HDIW is discharged to the rear surface of the wafer W in the pre-treatment process and the chemical liquid treatment process, and the chemical liquid is discharged to the central portion of the wafer W at 1400 ml/min for 40 seconds in the chemical liquid treatment process.

A consumption of the chemical liquid in the chemical liquid treatment process is reduced significantly to 138 ml in the experimental example, as compared to 933 ml in the comparative example (a reduction of 85.3%). A total waste liquid amount (corresponding to a total discharge amount of the temperature control HDIW to the rear surface of the wafer W plus a total discharge amount of the chemical liquid) in the chemical liquid treatment process is largely reduced to 590 ml in the experimental example, as compared to 933 ml in the comparative example (a reduction of 36.8%). As for the in-plane uniformity of the processing results, in the comparative example, an average etching amount is found to be 9.60 Å, a difference between the maximum and minimum etching amounts is found to be 3.51 Å, and the uniformity is found to be 16.85%. In the experimental example, on the other hand, the average etching amount is found to be 10.13 Å, the difference between the maximum and minimum etching amounts is found to be 3.45 Å, and the uniformity is found to be 17.47%, showing some improvement.

In a modification of the exemplary embodiment, the processing device 16 may be provided with a temperature measuring device (temperature measurer) configured to measure the temperature distribution of the wafer W (at least the temperature of the central portion and the temperature of the outer peripheral portion PR of the wafer W). The temperature measuring device may be configured by, for example, a thermo camera, an infrared thermometer, or the like. The temperature measuring device is schematically shown in FIG. 2 by being assigned a reference numeral 70. Based on a temperature measurement result obtained by this temperature measuring device 70, the processing conditions for the individual sub-processes of the chemical liquid treatment process, particularly processing conditions for the rear surface non-heating scan discharge sub-process S2 may be changed to adjust the temperature distribution of the wafer W.

Examples of changing the processing conditions include the following.

(1) Changing the time during which the movement of the chemical liquid nozzle 41C to the outer peripheral portion PR of the wafer W is stopped.

(2) Changing the moving speed of the chemical liquid nozzle 41C when moving the landing point of the chemical liquid on the front surface of the wafer W from the central portion to the outer peripheral portion PR of the wafer W. For example, the moving speed is made constant, or made faster as the landing point of the chemical liquid approaches the outer peripheral portion PR.

(3) Changing the moving speed of the chemical liquid nozzle 41C when moving the landing point of the chemical liquid on the front surface of the wafer W from the outer peripheral portion PR of the wafer W to the central portion of the wafer W. For example, the moving speed is made constant, or made slower as the landing point of the chemical liquid approaches the central portion of the wafer W.

(4) Setting the discharge flow rate of the chemical liquid from the chemical liquid nozzle 41C when the landing point of the chemical liquid on the front surface of the wafer W is at the outer peripheral portion PR to be larger than the discharge flow rate when the landing point of the chemical liquid is at the central portion of the wafer W.

Also, the processing conditions for (1) to (4) may be determined in advance based on the temperature measured by the temperature measuring device 70 or the etching amount distribution measured by a measuring device in a preliminary processing test, and may be reflected in the processing recipe in advance.

Below, effects of the above-described exemplary embodiments will be discussed.

At the time of filing the present application, a chemical liquid treatment performed in a single-wafer liquid processing apparatus (the apparatus configured to process substrates one by one as shown in FIG. 2) includes a chemical liquid treatment using a high-price organic chemical liquid for the purpose of removing films or removing polymer residues in a BEOL process. If the concentration, components, or the like of such an organic chemical liquid changes, there is a likelihood that a non-negligible adverse effect may be caused on the processing result. For this reason, the chemical liquid once used in the processing of the wafer W is discarded without being recovered or reused. Therefore, there is a demand for minimizing the amount of the chemical liquid used to process every single sheet of wafer W.

However, if the amount of the chemical liquid is reduced (that is, if the discharge flow rate of the chemical liquid is reduced), the in-plane uniformity of the temperature of the wafer W deteriorates. In particular, when the heated chemical liquid is discharged only to the central portion of the wafer W during the chemical liquid treatment, the smaller the discharge flow rate of the chemical liquid is, the more significant the decrease in the temperature of the outer peripheral portion of the wafer W becomes, and the more significant the temperature difference between the central portion and the outer peripheral portion of the wafer W becomes. As an example, when the chemical liquid of 55° C. is discharged to the central portion of the wafer W at the flow rate of 1400 ml/min, the temperature difference between the central portion and the peripheral portion of the wafer W is 5.8° C., whereas when the flow rate is reduced to 200 ml/min, the temperature difference increases up to 10.6° C. If the temperature difference increases in this way, the processing results of the chemical liquid treatment may differ to a non-negligible extent between the outer peripheral portion and the central portion of the wafer W. Therefore, it is not desirable to reduce the discharge flow rate of the chemical liquid without taking any measures.

The above-stated demand for the reduction of the chemical liquid and the problem of the temperature distribution are found not only in the BEOL process but also in a chemical liquid treatment performed in the FEOL process.

Through experiments, it has been confirmed that by supplying a temperature control liquid (for example, HDIW) to a rear surface of a substrate at a large flow rate, it is possible to suppress deterioration in the in-plane uniformity of the temperature of the substrate even when the amount of a chemical liquid supplied to a front surface of the substrate is reduced. This is because an effect of the temperature control liquid on an in-plane temperature distribution of the substrate is enhanced significantly with the increase of the flow rate of the temperature control liquid, as compared to an effect of the chemical liquid.

However, when supplying the organic chemical liquid to the front surface of the substrate while supplying the temperature control liquid (HDIW) to the rear surface of the substrate, the temperature control liquid (HDIW) and the organic chemical liquid scattered from the substrate are mixed in the liquid receiving cup, and are drained from the single-wafer liquid processing apparatus into a factory waste liquid line in this mixed state. For this reason, if the temperature control liquid is supplied at the large flow rate, the amount of the waste liquid generated when processing every single sheet of substrate increases greatly, resulting in an increase of waste liquid processing costs. In addition, the mixed solution of the HDIW and the organic chemical liquid is treated as an organic waste liquid.

There is also known a single-wafer liquid processing apparatus configured to attract the entire rear surface of the substrate by a vacuum chuck and heat the substrate by a heater embedded in the vacuum chuck, thereby making the in-plane temperature distribution of the substrate uniform. If, however, the vacuum chuck is used, contaminants may adhere to the rear surface of the substrate, and the contaminants that have adhered to the rear surface of the substrate during a transfer of the substrate or in a previous process cannot be removed at the same time as the chemical liquid treatment on the front surface of the substrate. In this regard, there are many cases in which this apparatus cannot be applied. Furthermore, such an apparatus is not common and is expensive.

Also, there is known a single-wafer liquid processing apparatuses capable of discharging a liquid at different radial positions on the rear surface of the substrate. However, such an apparatus is not common and is expensive.

The above-described exemplary embodiment provides one solution to the aforementioned various problems. According to the above-described exemplary embodiment, by supplying the temperature control liquid intermittently (in the exemplary embodiment, corresponding to performing both the rear surface heating scan discharge sub-process S1 and the rear surface non-heating scan discharge sub-process S2), the amount of the waste liquid drained from the liquid processing apparatus during the chemical liquid treatment can be reduced. In addition, by performing scan discharge of the chemical liquid from a chemical liquid nozzle when the temperature control liquid is not being supplied, the in-plane uniformity of the temperature of the substrate (and therefore the processing result of the chemical liquid treatment) can be improved.

FIG. 8 is a block diagram of processing circuitry for performing computer-based operations described herein. FIG. 8 illustrates processing circuitry 805 that may be used to control any computer-based control processes, descriptions or blocks in flowcharts can be understood as representing modules, segments or portions of code which include one or more executable instructions for implementing specific logical functions or steps in the process, and alternate implementations are included within the scope of the exemplary embodiments of the present advancements in which functions can be executed out of order from that shown or discussed, including substantially concurrently or in reverse order, depending upon the functionality involved, as would be understood by those skilled in the art. The various elements, features, and processes described herein may be used independently of one another or may be combined in various ways. All possible combinations and sub-combinations are intended to fall within the scope of this disclosure.

In FIG. 8, the processing circuitry 805 includes a processor (CPU) 835 which performs one or more of the control processes described above/below. The process data and instructions may be stored in memory 840. These processes and instructions (e.g., program 848) may also be stored on a storage medium disk 845 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the processing circuitry 805 communicates, such as a server or computer.

Further, the claimed advancements may be provided as a utility application, background daemon, or component of an operating system, or combination thereof, executing in conjunction with CPU 835 and an operating system such as Microsoft Windows, UNIX, Solaris, LINUX, Apple MAC-OS and other systems known to those skilled in the art.

The hardware elements in order to achieve the processing circuitry 805 may be realized by various circuitry elements. Further, each of the functions of the above described embodiments may be implemented by circuitry, which includes one or more processing circuits. A processing circuit includes a particularly programmed processor, for example, processor (CPU) 835, as shown in FIG. 8. A processing circuit also includes devices such as an application specific integrated circuit (ASIC) and conventional circuit components arranged to perform the recited functions.

In FIG. 8, the processing circuitry 805 includes a CPU 835 which performs the processes described above. The processing circuitry 805 may be a general-purpose computer or a particular, special-purpose machine.

Alternatively, or additionally, the CPU 835 may be implemented on an FPGA, ASIC, PLD or using discrete logic circuits, as one of ordinary skill in the art would recognize. Further, CPU 835 may be implemented as multiple processors cooperatively working in parallel to perform the instructions of the inventive processes described above.

The processing circuitry 805 in FIG. 8 also includes a network controller such as an Intel Ethernet PRO network interface card from Intel Corporation of America, for interfacing with network 810 via the network interface 850. As can be appreciated, the network 810 can be a public network, such as the Internet, or a private network such as an LAN or WAN network, or any combination thereof and can also include PSTN or ISDN sub-networks. The network 810 can also be wired, such as an Ethernet network, or can be wireless such as a cellular network including EDGE, 3G and 4G wireless cellular systems. The wireless network can also be Wi-Fi, Bluetooth, or any other wireless form of communication that is known.

The processing circuitry 805 further includes a display controller/display interface 865, such as a graphics card or graphics adaptor for interfacing with display 870, such as a monitor. A peripheral interface 855 interfaces with external devices 860 such as a keyboard, mouse, touch screen panel, etc. Peripheral interface 855 also connects to a variety of peripherals including printers and scanners. A processing circuitry system 800 can include the processing circuitry 805, along with a computer server 830, a cloud storage server 825, a web server 820, and a remote computer 815 which are connected to the processing circuitry 805 via the network 810. A description of the general features and functionality of the display 870, keyboard and/or mouse, as well as the display interface 865, the peripheral interface 855, the network interface 850, the computer server 830, the cloud storage server 825, the web server 820, and the remote computer 815 is omitted herein for brevity as these features are known.

The exemplary circuit elements described in the context of the present disclosure may be replaced with other elements and structured differently than the examples provided herein. Moreover, circuitry configured to perform features described herein may be implemented in multiple circuit units (e.g., chips), or the features may be combined in circuitry on a single chipset.

The functions and features described herein may also be executed by various distributed components of a system. For example, one or more processors may execute these system functions, wherein the processors are distributed across multiple components communicating in a network. The distributed components may include one or more client and server machines, which may share processing, in addition to various human interface and communication devices (e.g., display monitors, smart phones, tablets, personal digital assistants (PDAs)). The network may be a private network, such as a LAN or WAN, or may be a public network, such as the Internet. Input to the system may be received via direct user input and received remotely either in real-time or as a batch process. Additionally, some implementations may be performed on modules or hardware not identical to those described. Accordingly, other implementations are within the scope that may be claimed.

Here, it should be noted that the above-described exemplary embodiments are illustrative in all aspects and are not anyway limiting. The above-described exemplary embodiments may be omitted, replaced and modified in various ways without departing from the scope and the spirit of claims.

The substrate as a processing target is not limited to the semiconductor wafer, and may be any of various types of substrates for use in the field of semiconductor device manufacture, such as a glass substrate, a ceramic substrate, and so forth.

According to the exemplary embodiment, it is possible to improve in-plane temperature uniformity of the substrate while reducing the consumption amount of the chemical liquid.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. A substrate processing apparatus, comprising:
a substrate holder configured to hold a substrate having a first surface and a second surface in a horizontal posture;
a rotational driver configured to rotate the substrate holder and the substrate held by the substrate holder around a vertical axis;
a first fluid supply configured to supply a fluid to the first surface of the substrate held by the substrate holder;
a second fluid supply configured to supply a fluid to the second surface of the substrate held by the substrate holder; and
circuitry,
wherein the circuitry controls the rotational driver, the first fluid supply, and the second fluid supply to perform:
a pre-treatment process of supplying a heated fluid to the second surface of the substrate and supplying a pre-wetting liquid to the first surface of the substrate, while rotating the substrate at a first rotation speed; and
a chemical liquid treatment process of performing, after the pre-treatment process is performed, a chemical liquid treatment on the first surface by supplying a chemical liquid to the first surface of the substrate and concurrently supplying the heated fluid to the second surface of the substrate intermittently, while rotating the substrate at a second rotation speed.

2. The substrate processing apparatus of claim 1,
wherein the first rotation speed is equal to or higher than the second rotation speed.

3. The substrate processing apparatus of claim 1,
wherein the circuitry causes the second fluid supply to perform a discharge of the heated fluid onto the second surface of the substrate and a stop of the discharge of the heated fluid onto the second surface of the substrate at least twice during the chemical liquid treatment process.

4. The substrate processing apparatus of claim 1,
wherein the first fluid supply includes a nozzle configured to discharge the chemical liquid, and a nozzle moving structure configured to move the nozzle, and
in a first period during which the heated fluid is not supplied from the second liquid supply to the second surface of the substrate within a period during which the chemical liquid treatment process is being performed, the circuitry controls the nozzle to discharge the chemical liquid to the first surface of the substrate, while moving a landing point of the chemical liquid on the first surface of the substrate from a central portion to an outer peripheral portion of the substrate by using the nozzle moving structure.

5. The substrate processing apparatus of claim 4,
wherein in the first period, the circuitry controls the nozzle to discharge the chemical liquid to the outer peripheral portion of the first surface of the substrate in a state that movement of the nozzle by the nozzle moving structure is stopped for a predetermined time after the landing point of the chemical liquid on the first surface of the substrate reaches the outer peripheral portion.

6. The substrate processing apparatus of claim 5,
wherein the predetermined time is less than three seconds.

7. The substrate processing apparatus of claim 4,
wherein in the first period, the circuitry controls a moving speed of the nozzle to be constant when moving the landing point of the chemical liquid from the central portion to the outer peripheral portion of the substrate, or controls the moving speed to be increased as the landing point approaches the outer peripheral portion.

8. The substrate processing apparatus of claim 4,
wherein in the first period, the circuitry controls the first fluid supply such that a discharge flow rate of the chemical liquid from the nozzle when the landing point of the chemical liquid is at the outer peripheral portion is larger than a discharge flow rate of the chemical liquid from the nozzle when the landing point of the chemical liquid is at the central portion.

9. The substrate processing apparatus of claim 4,
wherein in the first period, after the landing point of the chemical liquid on the first surface of the substrate reaches the outer peripheral portion, the circuitry controls the nozzle to discharge the chemical liquid to the first surface of the substrate, while moving the landing point of the chemical liquid from the outer peripheral portion to the central portion of the substrate by using the nozzle moving structure.

10. The substrate processing apparatus of claim 9,
wherein in the first period, the circuitry controls a moving speed of the nozzle to be constant when moving the landing point of the chemical liquid from the outer peripheral portion to the central portion of the substrate, or controls the moving speed to be decreased as the landing point approaches the central portion.

11. The substrate processing apparatus of claim 1, further comprising:
a temperature measurer configured to measure a surface temperature of at least a central portion and an outer peripheral portion of the first surface of the substrate held by the substrate holder,
wherein the first fluid supply includes a nozzle configured to discharge the chemical liquid, and a nozzle moving structure configured to move the nozzle, and
based on a temperature measurement result of the temperature measurer, the circuitry moves the nozzle by using the nozzle moving structure to adjust a landing point of the chemical liquid on the first surface of the substrate.

12. The substrate processing apparatus of claim 1,
wherein the chemical liquid supplied to the first surface of the substrate has a temperature ranging from 30° C. to 80° C.

13. The substrate processing apparatus of claim 1,
wherein the pre-wetting liquid is de-ionized water or functional water in which ammonia or ozone is dissolved in de-ionized water.

14. The substrate processing apparatus of claim 13,
wherein the pre-wetting liquid is functional water with an ammonia concentration of 10 ppm or less, or functional water with an ozone concentration of 20 ppm or less.

15. The substrate processing apparatus of claim 1,
wherein the chemical liquid is a mixed solution of tetramethylammonium hydroxide (TMAH) and hydrogen peroxide, ammonia, a mixed solution of ammonia and hydrogen peroxide, choline, a mixed solution of choline and hydrogen peroxide, or TMAH.

16. A substrate processing method, comprising:
supplying a pre-wetting liquid to a first surface of a substrate and also supplying a heated fluid to a second surface of the substrate, while rotating the substrate at a first rotation speed; and
performing, after the supplying of the pre-wetting liquid and the supplying of the heated fluid are performed, a chemical liquid treatment on the first surface by supplying a chemical liquid to the first surface of the substrate from a chemical liquid nozzle and concurrently supplying the heated fluid to the second surface of the substrate intermittently, while rotating the substrate at a second rotation speed.

17. The substrate processing method of claim 16,
wherein during the performing of the chemical liquid treatment, a discharge of the heated fluid onto the second surface of the substrate and a stop of the discharge of the heated fluid onto the second surface of the substrate are performed at least twice.

18. The substrate processing method of claim 16,
wherein in a first period during which the heated fluid is not supplied to the second surface of the substrate within a period during which the performing of the chemical liquid treatment is being performed, the chemical liquid is discharged from the chemical liquid nozzle to the first surface of the substrate, while moving a landing point of the chemical liquid on the first surface of the substrate from a central portion to an outer peripheral portion of the substrate or from the outer peripheral portion to the central portion of the substrate by moving the chemical liquid nozzle.

19. The substrate processing method of claim 18,
wherein in the first period, the moving of the chemical liquid nozzle is stopped for a predetermined time when the landing point of the chemical liquid on the first surface of the substrate has reached the outer peripheral portion, and the chemical liquid is supplied to the outer peripheral portion for the predetermined time.
